(19) United States
(12) Patent Application Publication
(10) Pub. No.: US 2024/0295763 A1
(43) Pub. Date: Sep. 5, 2024

(54) ADVANCED OPTICAL MATERIALS AND STRUCTURES

(71) Applicant: Meta Platforms Technologies, LLC, Menlo Park, CA (US)

(72) Inventors: Kenneth Alexander Diest, Kirkland, WA (US); Spencer Allan Wells, Seattle, WA (US); Zhaohui Yang, Sammamish, WA (US); Nihar Ranjan Mohanty, Snoqualmie, WA (US); Richard Farrell, Seattle, WA (US); Jilin Yang, Bellevue, WA (US); Ehsan Arbabi, San Jose, CA (US)

(21) Appl. No.: 18/515,795

(22) Filed: Nov. 21, 2023

Related U.S. Application Data
(60) Provisional application No. 63/488,252, filed on Mar. 3, 2023.
(60) Provisional application No. 63/488,726, filed on Mar. 6, 2023.
(60) Provisional application No. 63/488,725, filed on Mar. 6, 2023.
(60) Provisional application No. 63/493,090, filed on Mar. 30, 2023.

(51) Int. Cl. G02F 1/05; C03C 17/23; C30B 29/30; C30B 29/32; G02B 6/34; G03F 7/00

(52) U.S. Cl. CPC G02F 1/05; C03C 17/23; C30B 29/30; C30B 29/32; G02B 6/34; G03F 7/0002; G03F 7/0005; C03C 2217/228; C03C 2217/23; C03C 2217/92

(57) ABSTRACT

A device includes a pair of electrodes and a dynamic material disposed between the pair of electrodes, the dynamic material including a crystalline microstructure configured to change between at least two states in response to a change in an electric field between the two electrodes. A material includes tetragonal lead magnesium niobate-lead titanate (PMN-PT) and at least one lanthanide series element. A method includes doping a lead magnesium niobate-lead titanate material with at least one lanthanide series element, and processing the PMN-PT material to form tetragonal PMN-PT. A further method includes forming a low refractive index nanostructured grating over a carrier substrate, forming a high refractive index layer over the low refractive index grating to produce a nanostructured coupling element, forming an adhesive layer over the nanostructured coupling element, and affixing the nanostructured coupling element to a high index waveguide.

### CROSS-REFERENCE TO RELATED APPLICATIONS

This application claims the benefit of priority under 35 U.S.C. § 119(e) of U.S. Provisional Application No. 63/488,252, filed Mar. 3, 2023, U.S. Provisional Application No. 63/488,726, filed Mar. 6, 2023, U.S. Provisional Application No. 63/488,725, filed Mar. 6, 2023, and U.S. Provisional Application No. 63/493,090, filed Mar. 30, 2023, the contents of which are incorporated herein by reference in their entirety.

### BRIEF DESCRIPTION OF THE DRAWINGS

The accompanying drawings illustrate a number of exemplary embodiments and are a part of the specification. Together with the following description, these drawings demonstrate and explain various principles of the present disclosure.

FIG. 1 illustrates an example of an electroded multidomain material.

FIG. 2 illustrates a further example of an electroded multidomain material.

FIG. 3 is a schematic illustration of a portion of a device including an electrostrictive phase change material.

FIG. 4 is a schematic illustration of a portion of a device including a ferroelectric phase change material.

FIG. 5 shows domain polarization directions for exemplary phases of a piezoelectric material.

FIG. 6 illustrates example orientations for rhombohedral, monoclinic, and tetragonal unit cells.

FIG. 7 is schematic of device structures including a layer of an electrostrictive phase change material.

FIG. 8 is a PMN-PT phase diagram and plot of lattice mismatch for undoped PMN-37% PT.

FIG. 9 illustrates an example process for forming a nano-replicated coupling element architecture according to some embodiments.

FIG. 10 demonstrates the integration of a functional layer into the nano-replication process of FIG. 9 according to certain embodiments.

FIG. 11 shows the formation of a nanostructured coupling element including a selectively deposited high-index layer over a low-index blazed grating according to some embodiments.

FIG. 12 is an illustration of exemplary augmented-reality glasses that may be used in connection with embodiments of this disclosure.

FIG. 13 is an illustration of an exemplary virtual-reality headset that may be used in connection with embodiments of this disclosure.

Throughout the drawings, identical reference characters and descriptions indicate similar, but not necessarily identical, elements. While the exemplary embodiments described herein are susceptible to various modifications and alternative forms, specific embodiments have been shown by way of example in the drawings and will be described in detail herein. However, the exemplary embodiments described herein are not intended to be limited to the particular forms disclosed. Rather, the present disclosure covers all modifications, equivalents, and alternatives falling within the scope of the appended claims.

### DETAILED DESCRIPTION OF EXEMPLARY EMBODIMENTS

### Speckle Mitigation Devices Including Dynamic Microstructural Materials

Laser speckle is a fundamental issue with conventional laser illuminated displays and other systems utilizing coherent light sources. Speckle mitigation approaches have focused on mechanical motion/translation of either particles or hazy surfaces or by using patterned gratings. Some examples of speckle mitigation systems include physically vibrating a piece of ground glass, mechanically moving diffusers, rapidly pulsing a laser, and/or using pre-patterned switchable LC gratings. Unfortunately, mechanical approaches are typically difficult to integrate robustly in commercially-relevant systems. Additionally, creating intentional gratings can send a large fraction of light in directions other than the intended display direction.

This disclosure describes several approaches to speckle reduction: 1) electrically changing the magnitude of optical scatter in a material, 2) thermally changing the magnitude of optical scatter in a material, 3) electrically changing the distribution of optical scatter in a material, 4) thermally changing the distribution of optical scatter in a material, combining both thermal and electrical impulses to change the magnitude of optical scatter in a material, and/or 5) combining both thermal and electrical impulses to change the distribution of optical scatter in a material. As described herein, electric field and material switching may happen quickly enough that a speckle pattern becomes imperceptible. For example, switching frequencies may be greater than 100 Hz (e.g., approximately 200, 300, 400, 500, or 1000 Hz)

Various microstructures may provide desired levels of speckle reduction. One example system may utilize multidomain ferroelectric materials that undergo a phase transformation to a single domain. Additionally, or alternatively, an example system may utilize multidomain ferroelectrics that rearrange their microstructure. In this example, the domain size and magnitude of a refractive index difference between different states may change with electric field. Some example systems may utilize electrostrictive ceramics or crystalline materials that undergo a phase transformation to multidomain ferroelectrics.

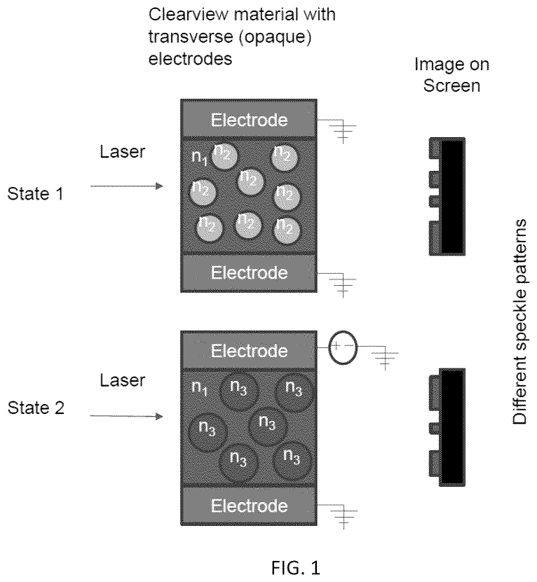

In some examples, dynamic haze may be generated in a material having pre-existing bulk haze. This is a non-mechanical solution that doesn't require sophisticated high frequency electronics applicability in augmented reality, virtual reality, and/or other applications utilizing laser light sources. A ferroelectric or electrostrictive material (ceramic or crystalline composition) may be used. Referring to FIG. 1, a multidomain material, such as a ferroelectric material, may be disposed between a pair of electrodes. FIG. 1 shows the electrodes arranged transversely (i.e., parallel to the multidomain material) such that laser light passes through the multidomain material without passing through either of the electrodes. As such, opaque electrodes may be used in this example. An antireflective (AR) coating may be disposed on an incident and/or exit surface of the multidomain material so that little or no laser light is reflected. In at least one example, the multidomain material may be utilized as a waveguide when relatively lower voltages are used.

In a first voltage state (e.g., 0 V differential between the electrodes), the multidomain material may be in a first state. In a second voltage state, (e.g., a non-zero voltage differential between the electrodes) the multidomain material may be in a second state. The coherent laser light may produce different speckle patterns when passing through the multidomain material in the first and second voltage states. By dynamically causing the multidomain material to alternate between the first and second states, the visual speckle pattern may be mitigated.

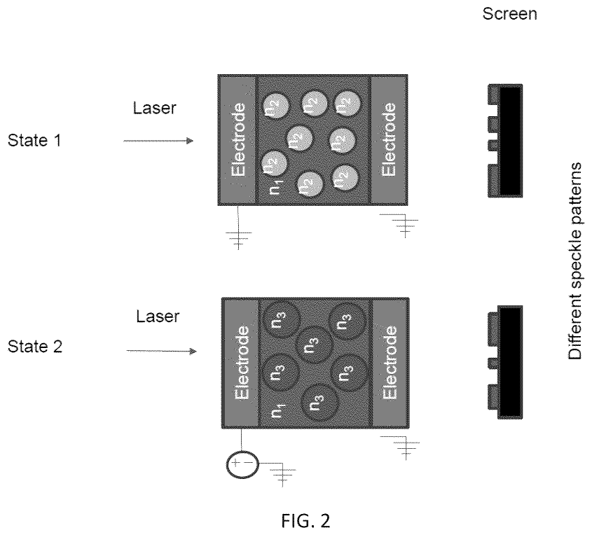

FIG. 2 illustrates an alternative device orientation where the multidomain material is disposed between two electrodes overlapping and covering the incident and exit surfaces. The electrodes may be transparent to allow laser light to pass through the electrodes in this example. AR coatings may be applied to surfaces of the electrodes and/or the multidomain material so that little or no laser light is reflected.

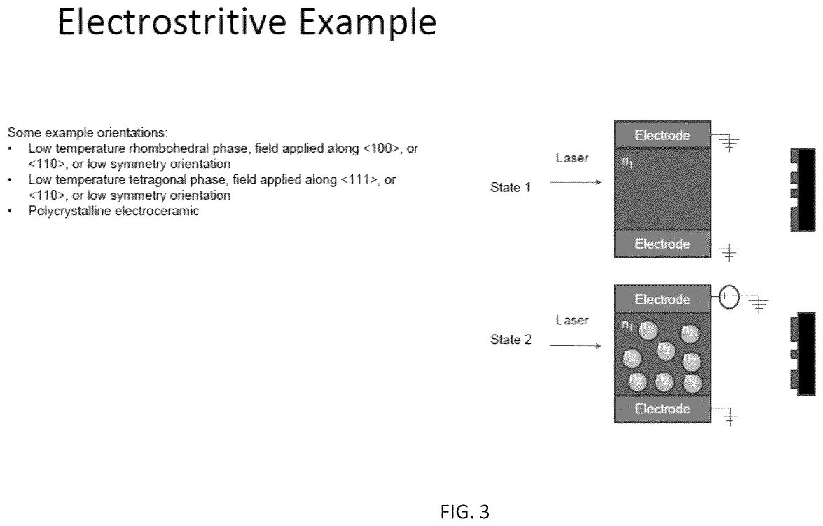

FIG. 3 illustrates a speckle mitigation device that includes an electrostrictive material. As shown, the electrostrictive material may be disposed between two electrodes and various voltage differentials may be applied to the electrodes to change the state of the electrostrictive material. Some example orientations may include 1) a low temperature rhombohedral phase, field applied along <100>, or <110>, or low symmetry orientation, 2) a low temperature tetragonal phase, field applied along <111>, or <110>, or low symmetry orientation, or 3) a polycrystalline electro-ceramic.

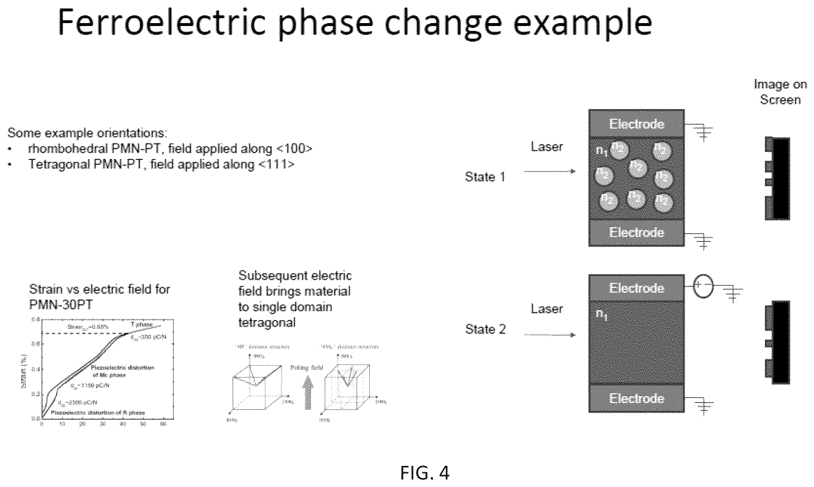

FIG. 4 illustrates a speckle mitigation device that includes a ferroelectric material. As shown, the ferroelectric material may be disposed between two electrodes and various voltage differentials may be applied to the electrodes to change the state of the ferroelectric material. Some example orientations may include 1) a rhombohedral PMN-PT, field applied along <100> or 2) a tetragonal PMN-PT, field applied along <111>.

### Transparent Electrostrictive Materials Including Oriented Crystalline Structures and Devices Including the Same

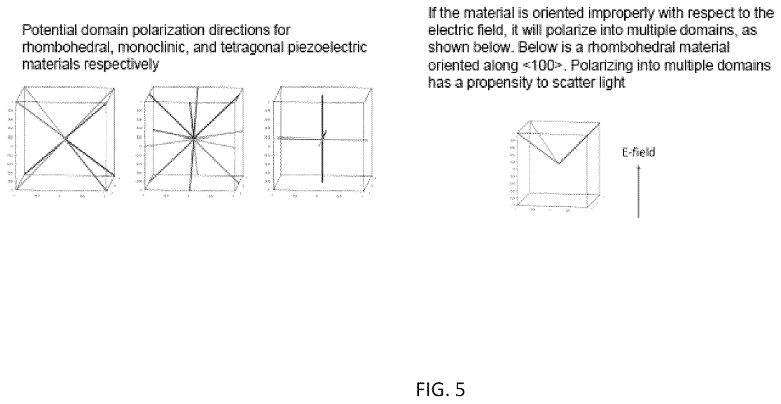

Electrostrictive materials may be utilized as actuators, including actuators having a degree of transparency. However, these materials may be fundamentally limited by the temperature, electric field, and composition range they can operate in. Electrostrictive materials are generally understood to have isotropic electrical and mechanical properties and are generally considered to perform similar to other crystals or ceramics. However, in many actuator applications, the composition of an electrostrictive ceramic for a given range of operational temperatures may be chosen proximate to a phase transformation boundary, which may lead to larger, desirable field-induced deformations. With reference to FIG. 5 and the example of a rhombohedral material oriented along <100>, concomitant E-field-induced nucleation and growth of randomly-oriented domains within the material may contribute to unwanted light scattering and an accompanying degradation of optical performance.

Disclosed are domain engineered electrostrictive ceramic compositions that may be crystallographically aligned with respect to the polar axis of a corresponding low temperature polar phase such that during operation the applied electric field is oriented substantially parallel to the polar axis (e.g., parallel or misaligned by an angle of up 5 degrees). In conjunction with an E-field induced phase transformation, this relationship can result in the formation of spatially-aligned domains within the material or even a single crystal composition, which exhibits comparatively favorable optical properties, including higher transmissivity owing to fewer and/or smaller light scattering regions. When exposed to an electric field (E-field), the domain engineered electrostrictive ceramics may produce a commercially relevant strain output while also maintaining desirable optical properties.

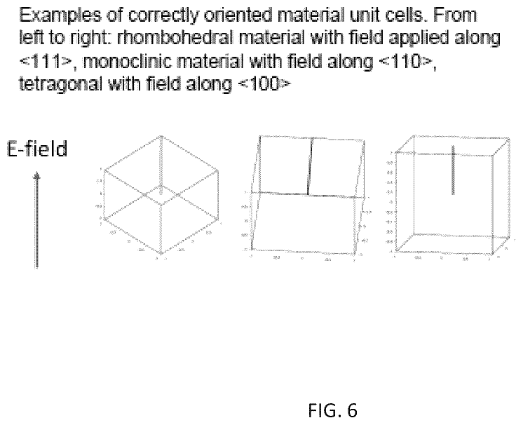

Example materials, including PMN-PT compositions, may have a high temperature cubic phase and a low temperature polar phase (e.g., a tetragonal, orthorhombic, or rhombohedral phase). In certain embodiments, a PMN-PT material having a low temperature tetragonal phase may be preferentially oriented along <100>, a PMN-PT material having a low temperature orthorhombic phase may be preferentially oriented along <110>, and a PMN-PT material having a low temperature rhombohedral phase may be preferentially oriented along <111>. The composition (e.g., PT content) and orientation of an electrostrictive ceramic may be selected based on a particular use case, including the desired strain output and the temperature range of operation. FIG. 6 illustrates various domain polarization directions for rhombohedral, monoclinic, and tetragonal piezoelectric materials. By aligning the orientation of the low temperature phase with the electric field, when the domain engineered material undergoes a cubic to low symmetry phase transformation, it may remain transparent.

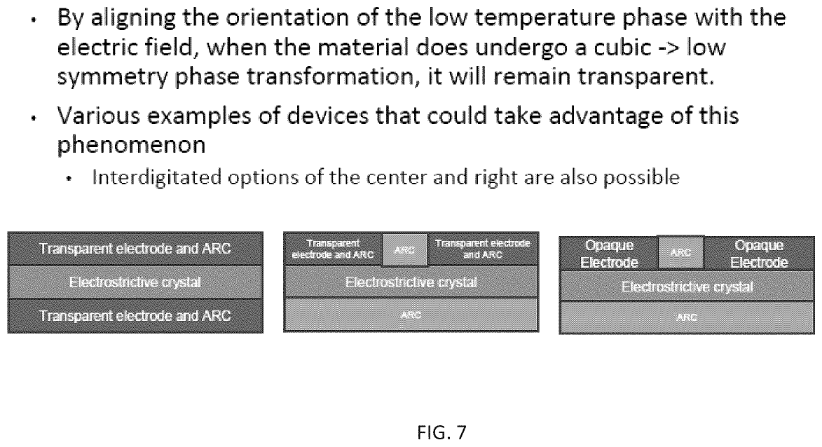

FIG. 7 shows example electrostrictive device architectures (e.g., actuators) as described herein. As shown, domain engineered electrostrictive crystals and/or crystalline materials may be disposed between and/or adjacent to transparent and/or opaque electrodes. Anti-reflective coatings (ARCs) may be included within and/or may be disposed over the electrode(s) and/or domain engineered electrostrictive material.

### Doped Tetragonal Lead Magnesium Niobate-Lead Titanate

Lead magnesium niobate-lead titanate (PMN-PT) crystal growth is expensive and has only been commercialized for a narrow range of PMN-PT compositions having approximately 28-32% PT. Tetragonal PMN-PT (corresponding to PMN-PT with greater than approximately 35% PT) has many interesting properties but has not been investigated to the same degree as rhombohedral PMN-PT (having less than approximately 35% PT). Growing crack-free, large diameter (i.e., greater than 2 in) tetragonal PMN-PT crystals has not been demonstrated. One of the challenges in commercializing tetragonal PMN-PT is the difficulty in crystal growth. For any usable application, the material must be crack-free. One of the factors limiting crystal growth is that the material spontaneously polarizes upon cooling, producing large strains.

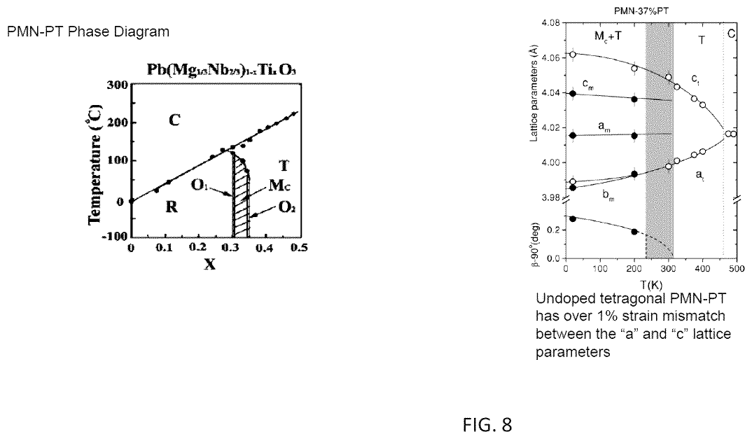

Referring to FIG. 8, shown are a phase diagram and strain plot for undoped tetragonal PMN-PT with 37% PT. Undoped tetragonal PMN-PT may have over 1% strain mismatch between the “a” and “c” lattice parameters.

An additional difference between these systems is the role of compositional gradients. PT ceramics are compositionally uniform, but PMN-PT boules often include compositional gradients. These composition gradients and potential temperature gradients during cooling further exacerbate these problems with PMN-PT.

Crack formation during crystal growth is a large problem for tetragonal PMN-PT. However, doping may solve this cracking issue. Doping during formation of tetragonal PMN-PT may provide various advantages, including the ability to provide larger diameter tetragonal PMN-PT crystals, single crystal doping, etc. Potential dopants may include less than 10 mol % of any lanthanide series element or combination of lanthanide elements (e.g., lanthanum, cerium, praseodymium, neodymium, promethium, samarium, europium, gadolinium, terbium, dysprosium, holmium, erbium, thulium, ytterbium, and/or lutetium).

Doping lead titanate is known to decrease tetragonality and reduce internal stress. While doping of tetragonal PMN-PT has not been demonstrated, doped tetragonal PMN-PT may be expected to behave in a similar manner to doped lead titanate during crystal formation. A linkage between doping and enabling large-scale crystal growth has also not yet been demonstrated. Work on crack reduction has focused on either rhombohedral PMN-PT and/or creating compositionally homogeneous PMN-PT. Accordingly, doped tetragonal PMN-PT may overcome issues commonly present in crystalline tetragonal PMN-PT.

### Nanostructured Coupling Element for Waveguide Applications

A waveguide display system may include a micro-display module and waveguide optics for directing a display image to a user. The waveguide optics may include input-coupling and output-coupling elements such as surface relief gratings that are configured to couple light into and out of the waveguide. A vertical grating coupler, for instance, may be configured to change an out-of-plane wave-vector direction of light to an in-plane waveguide direction, or vice versa, and accordingly direct the passage of light through the waveguide display.

In exemplary systems, the waveguide optics may be advantageously configured to create illuminance uniformity and a wide field of view (FOV). The FOV relates to the angular range of an image observable by a user, whereas illuminance uniformity may include both the uniformity of image light over an expanded exit pupil (exit pupil uniformity) and the uniformity of image light over the FOV (angular uniformity). As will be appreciated, an input-coupling grating may determine the angular uniformity and coupling efficiency of image light. Moreover, the field of view of an augmented reality waveguide may be strongly dependent on the refractive index of the waveguide medium.

Notwithstanding recent developments, it would be beneficial to develop performance-enhancing waveguide optics, and particularly input-coupling and output-coupling elements that are versatile and co-integrated with high refractive index waveguides. In accordance with various embodiments, a method of manufacturing a coupling element for a waveguide display may include (a) forming a low refractive index nanostructured grating over a carrier substrate, (b) forming a high refractive index layer over the low refractive index grating to produce a nanostructured coupling element, (c) forming an adhesive layer over the nanostructured coupling element, and (d) affixing the nanostructured coupling element to a high index waveguide. Optionally, the method may additionally include removing the nanostructured element from the carrier substrate.

In an example method, the nanostructured grating may include a slanted grating or a blazed grating that may be imprinted using nanoimprint lithography and replicated over the carrier substrate. Formation of the nanostructured grating may include a continuous process such as a roll-to-roll process. In various embodiments, a refractive index of the nanostructured grating may be less than approximately 1.6. The nanostructured grating may be formed directly over a carrier substrate that may include glass or a polymer.

A coupling element may be formed by depositing a high refractive index layer over the low refractive index grating. In various embodiments, a refractive index of the high refractive index layer may be greater than a refractive index of the nanostructured grating, e.g., greater than approximately 1.6. Example high refractive index materials include silicon carbide, lithium niobate, and high refractive index glasses, although further high refractive index compositions are contemplated.

Any suitable method may be used to form the high refractive index layer, which may backfill the structure of the low refractive index grating. Example methods include, but are not limited to, chemical vapor deposition, epitaxial deposition, atomic layer deposition, and electron beam deposition. A deposition process for forming the high refractive index layer may be uni-directional or multi-directional, and may form a conformal layer with respect to the grating architecture. In some examples, formation of the high refractive index layer may be preceded by selective surface activation of a surface of the low refractive index grating.

In various aspects, the presently disclosed additive process may be modified to facilitate the integration of one or more functional layers into a nanostructured coupling element. Co-integrated functional layers may include optical stacks such as anti-reflective coatings, or reflective or transmissive polarizers, and thin optics such as diffractive lenses, eye-tracking elements, and dimming elements.

For affixing a nanostructured coupling element to a waveguide, any suitable adhesive layer may be used, such as curable liquid or solid adhesives. An adhesive layer may have a high refractive index, e.g., greater than at least approximately 1.6. For instance, an adhesive layer may include a high refractive index dielectric material (e.g., TiO₂) that is fusion bonded to a high refractive index waveguide.

According to particular embodiments, an adhesive layer may be formed directly over the high refractive index layer of a nanostructured coupling element and the nanostructured coupling element may be affixed to a high refractive index waveguide such that the land thickness between the high refractive index layer and the waveguide is less than approximately 100 nm, e.g., less than 100 nm, less than 50 nm, or less than 30 nm, including ranges between any of the foregoing values.

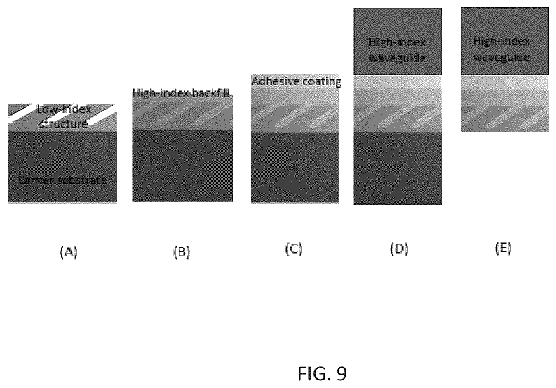

Referring to FIG. 9, illustrated is an example method for forming a nanostructured coupling element having a slanted grating. As shown in FIG. 9A, the method may include forming a low refractive index grating structure over a carrier substrate. The grating structure may be formed using a replication tool, for example, to form a 2D architecture over the carrier substrate. As shown in FIG. 9B, a high refractive index layer may be formed over the low refractive index grating to produce the nanostructured coupling element. In particular embodiments, the high refractive index layer may backfill the structure of the low refractive index grating. A top surface of the high refractive index layer may be planarized, e.g., using chemical mechanical polishing.

Turning to FIG. 9C, an adhesive layer may be formed over the nanostructured coupling element and, as shown in FIG. 9D, the nanostructured coupling element may be affixed to a high index waveguide. FIG. 9B shows removal of the carrier substrate from the waveguide architecture of FIG. 9D.

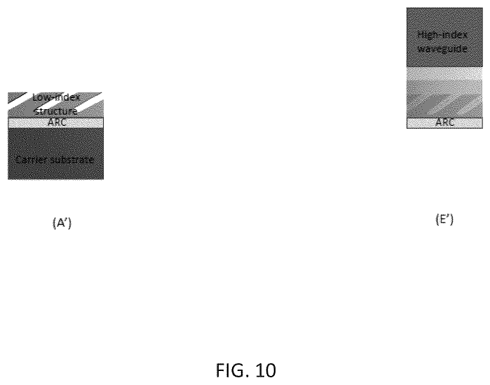

The co-integration of a functional layer such as an antireflective coating (ARC) into the waveguide architecture of FIG. 9 is shown in FIG. 10 where, with reference initially to FIG. 10A′, an ARC may be formed over the carrier substrate prior to forming the low refractive index grating structure. Subsequently, the carrier substrate may be removed from the waveguide architecture, as shown in FIG. 10E′ to form a multi-functional nanostructured coupling element.

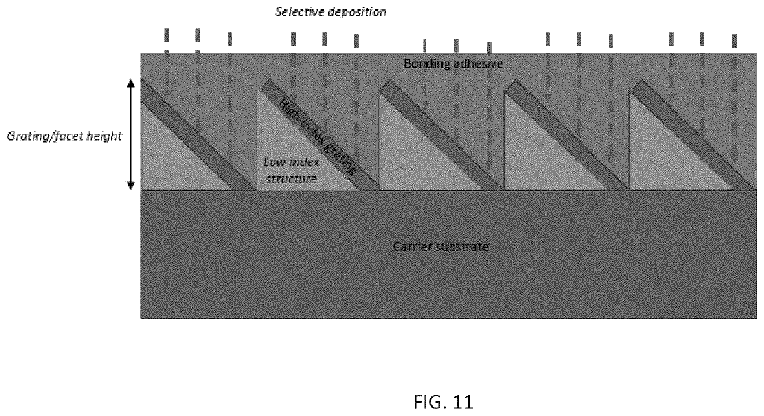

Referring to FIG. 11, shown is an alternate grating architecture and associated method of manufacture where a blazed low refractive index grating structure is formed over a carrier substrate. In accordance with certain embodiments, the geometry of the facets of the blazed grating, including height, pitch, angle, spacing, etc., may be controlled amongst the replicated structures. Following replication of the blazed grating, a selective deposition process may be used to form a high refractive index layer over the facets of the slanted grating and produce a 1D or 2D array of nanostructured coupling elements. Subsequently, an adhesive layer may be formed over the nanostructured coupling elements for affixing the structure to a waveguide (not shown).

According to certain embodiments, the facets may be disposed at any suitable oblique angle with respect to the carrier substrate and arranged with a constant or variable height and duty cycle so that the grating efficiency decreases along a primary light propagation direction.

In accordance with various embodiments, a waveguide coupling element is formed using an additive process where a low refractive index structure and a high refractive index layer are co-integrated and affixed to a waveguide. The waveguide medium may include a high refractive index material such as silicon carbide (SiC), lithium niobate (LiNbO₃), or a high index glass.

An example process may include initially forming/replicating nanostructured features from a low index material over a carrier substrate and subsequently forming a high refractive index layer over the nanostructured features. The nanostructured features may include a grating architecture such as a slanted or blazed (echelette) grating. In some examples, a slanted low index replicated grating may be backfilled with a high refractive index layer. In further embodiments, a slanted grating may be formed by directional deposition of a high refractive index layer over the inclined facets of a low refractive index blazed structure.

An over-formed thin adhesive coating may be configured to bond the coupling element to a high refractive index waveguide followed by optional removal of the carrier substrate. Suitable adhesives may include high index materials such as TiO₂, which may be fusion bonded to a surface of the waveguide. In some instantiations, one or more functional layers may be incorporated into the coupling element geometry. For instance, an antireflective coating (ARC) or polarization layer may be formed over the carrier substrate prior to forming the low index replication architecture. Relative to comparative techniques such as ion beam etching, the disclosed methods may be more economical while also enabling a broader array of in-coupling and out-coupling configurations.

### EXAMPLE EMBODIMENTS

Example 1: A device includes a pair of electrodes and a dynamic material disposed between the pair of electrodes, the dynamic material including a crystalline microstructure configured to change between at least two states in response to changes in an electric field between the two electrodes.

Example 2: The device of Example 1, where the dynamic material includes a multidomain ferroelectric material configured to undergo a phase transformation to a single domain material.

Example 3: The device of any of Examples 1 and 2, where the dynamic material includes a multidomain ferroelectric material configured to undergo microstructural rearrangement.

Example 4: The device of Example 3, where the microstructural rearrangement involves at least one of a change in domain size and a change in a magnitude of a refractive index difference.

Example 5: The device of any of Examples 1-4, where the dynamic material includes an electrostrictive ceramic or crystalline material configured to undergo a phase transformation to a multidomain ferroelectric material.

Example 6: The device of any of Examples 1-5, where the dynamic material includes an electrostrictive material, the electrostrictive material having a crystalline structure that is oriented to have a polar axis that is substantially parallel to an electric field generated when a voltage is applied between the pair of electrodes.

Example 7: The device of Example 6, where the electrostrictive material is rhombohedral, monoclinic, or tetragonal under the generated electric field.

Example 8: The device of any of Examples 6 and 7, where the electrostrictive material is cubic in the absence of the generated electric field.

Example 9: The device of any of Examples 6-8, where the electrostrictive material includes a single crystal or an oriented ceramic material.

Example 10: The device of any of Examples 6-9, where the electrostrictive material includes PMN-PT.

Example 11: The device of any of Examples 6-10, where the polar axis is aligned substantially parallel to the generated electric field when the electrostrictive material is in a low temperature phase.

Example 12: The device of Example 11, where the electrostrictive material is configured to be transparent when it is in the low temperature phase.

Example 13: A material includes tetragonal lead magnesium niobate-lead titanate (PMN-PT) and at least one lanthanide series element.

Example 14: The material of Example 13, where the at least one lanthanide series element is present at a concentration of approximately 10 mol % or less.

Example 15: The material of any of Examples 13 and 14, where the at least one lanthanide series element comprises at least one of lanthanum, cerium, praseodymium, neodymium, promethium, samarium, europium, gadolinium, terbium, dysprosium, holmium, erbium, thulium, ytterbium, or lutetium.

Example 16: A plurality of methods include (I) doping a lead magnesium niobate-lead titanate (PMN-PT) material with at least one lanthanide series element and processing the PMN-PT material to form tetragonal PMN-PT, or (II) forming a low refractive index nanostructured grating over a carrier substrate, forming a high refractive index layer over the low refractive index grating to produce a nanostructured coupling element, forming an adhesive layer over the nanostructured coupling element, and affixing the nanostructured coupling element to a high index waveguide.

Example 17: The plurality of methods of Example 16, where forming the nanostructured grating includes nanoimprint lithography.

Example 18: The plurality of methods of any of Examples 16 and 17, where forming the nanostructured grating includes nano-replication.

Example 19: The plurality of methods of any of Examples 16-18, where forming the nanostructured grating includes a roll-to-roll process.

Example 20: The plurality of methods of any of Examples 16-19, where the nanostructured grating includes a structure selected from a slanted grating and a blazed grating.

Example 21: The plurality of methods of any of Examples 16-20, where the nanostructured grating includes a 2D grating.

Example 22: The plurality of methods of any of Examples 16-21, where the carrier substrate includes glass or a polymer.

Example 23: The plurality of methods of any of Examples 16-22, further including selective surface activation of a surface of the nanostructured grating prior to forming the high refractive index layer.

Example 24: The plurality of methods of any of Examples 16-23, where the high refractive index layer backfills the nanostructured grating.

Example 25: The plurality of methods of any of Examples 16-24, where forming the high refractive index layer includes uni-directional deposition.

Example 26: The plurality of methods of any of Examples 16-25, where forming the high refractive index layer includes multi-directional deposition.

Example 27: The plurality of methods of any of Examples 16-26, where forming the high refractive index layer comprises conformal deposition.

Example 28: The plurality of methods of any of Examples 16-27, where forming the high refractive index layer includes a process selected from chemical vapor deposition, epitaxial deposition, atomic layer deposition, and electron beam deposition.

Example 29: The plurality of methods of any of Examples 16-28, where the high refractive index layer includes an inorganic solid selected from silicon carbide, lithium niobate, and a high-index glass.

Example 30: The plurality of methods of any of Examples 16-29, where forming the adhesive layer includes depositing a liquid adhesive.

Example 31: The plurality of methods of any of Examples 16-30, where a thickness of the adhesive layer between the high refractive index layer and the high index waveguide is less than approximately 100 nm.

Example 32: The plurality of methods of any of Examples 16-31, where a refractive index of the adhesive layer is at least approximately 1.6.

Example 33: The plurality of methods of any of Examples 16-32, where the adhesive layer includes a fusion-bonded dielectric coating.

Example 34: The plurality of methods of any of Examples 16-33, further including forming a functional layer over the carrier substrate prior to forming the nanostructured grating.

Example 35: The plurality of methods of any of Examples 16-34, where the functional layer includes an antireflective coating or a polarizing coating.

Example 36: A coupling element includes a low refractive index nanostructured grating having a nanostructured surface, a high refractive index layer disposed over the low refractive index nanostructured grating and backfilling nanostructured features in the grating, and an adhesive layer disposed over the high refractive index layer.

Embodiments of the present disclosure may include or be implemented in conjunction with various types of artificial-reality systems. Artificial reality is a form of reality that has been adjusted in some manner before presentation to a user, which may include, for example, a virtual reality, an augmented reality, a mixed reality, a hybrid reality, or some combination and/or derivative thereof. Artificial-reality content may include completely computer-generated content or computer-generated content combined with captured (e.g., real-world) content. The artificial-reality content may include video, audio, haptic feedback, or some combination thereof, any of which may be presented in a single channel or in multiple channels (such as stereo video that produces a three-dimensional (3D) effect to the viewer). Additionally, in some embodiments, artificial reality may also be associated with applications, products, accessories, services, or some combination thereof, that are used to, for example, create content in an artificial reality and/or are otherwise used in (e.g., to perform activities in) an artificial reality.

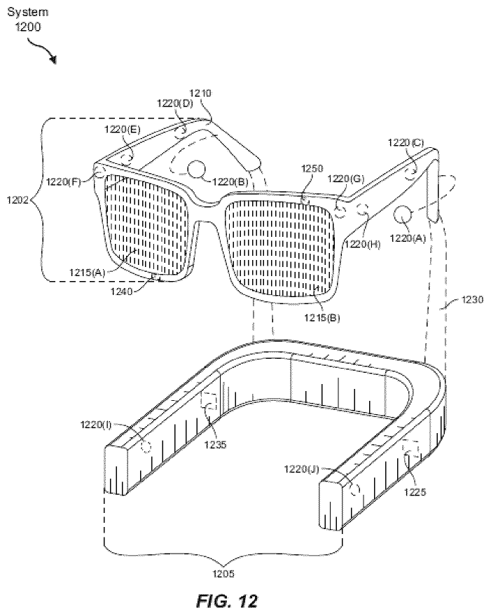

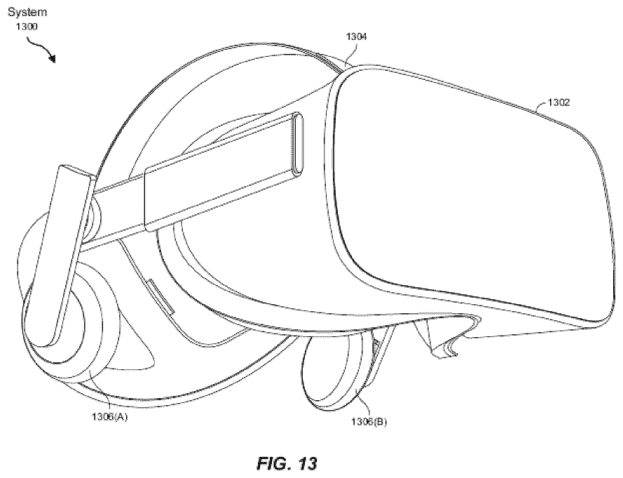

Artificial-reality systems may be implemented in a variety of different form factors and configurations. Some artificial-reality systems may be designed to work without near-eye displays (NEDs). Other artificial-reality systems may include an NED that also provides visibility into the real world (e.g., augmented-reality system 1200 in FIG. 12) or that visually immerses a user in an artificial reality (e.g., virtual-reality system 1300 in FIG. 13). While some artificial-reality devices may be self-contained systems, other artificial-reality devices may communicate and/or coordinate with external devices to provide an artificial-reality experience to a user. Examples of such external devices include handheld controllers, mobile devices, desktop computers, devices worn by a user, devices worn by one or more other users, and/or any other suitable external system.

Turning to FIG. 12, augmented-reality system 1200 may include an eyewear device 1202 with a frame 1210 configured to hold a left display device 1215(A) and a right display device 1215(B) in front of a user's eyes. Display devices 1215(A) and 1215(B) may act together or independently to present an image or series of images to a user. While augmented-reality system 1200 includes two displays, embodiments of this disclosure may be implemented in augmented-reality systems with a single NED or more than two NEDs.

In some embodiments, augmented-reality system 1200 may include one or more sensors, such as sensor 1240. Sensor 1240 may generate measurement signals in response to motion of augmented-reality system 1200 and may be located on substantially any portion of frame 1210. Sensor 1240 may represent a position sensor, an inertial measurement unit (IMU), a depth camera assembly, a structured light emitter and/or detector, or any combination thereof. In some embodiments, augmented-reality system 1200 may or may not include sensor 1240 or may include more than one sensor. In embodiments in which sensor 1240 includes an IMU, the IMU may generate calibration data based on measurement signals from sensor 1240. Examples of sensor 1240 may include, without limitation, accelerometers, gyroscopes, magnetometers, other suitable types of sensors that detect motion, sensors used for error correction of the IMU, or some combination thereof.

Augmented-reality system 1200 may also include a microphone array with a plurality of acoustic transducers 1220(A)-1220(J), referred to collectively as acoustic transducers 1220. Acoustic transducers 1220 may be transducers that detect air pressure variations induced by sound waves. Each acoustic transducer 1220 may be configured to detect sound and convert the detected sound into an electronic format (e.g., an analog or digital format). The microphone array in FIG. 12 may include, for example, ten acoustic transducers: 1220(A) and 1220(B), which may be designed to be placed inside a corresponding ear of the user, acoustic transducers 1220(C), 1220(D), 1220(E), 1220(F), 1220(G), and 1220(H), which may be positioned at various locations on frame 1210, and/or acoustic transducers 1220(I) and 1220(J), which may be positioned on a corresponding neckband 1205.

In some embodiments, one or more of acoustic transducers 1220(A)-(F) may be used as output transducers (e.g., speakers). For example, acoustic transducers 1220(A) and/or 1220(B) may be earbuds or any other suitable type of headphone or speaker.

The configuration of acoustic transducers 1220 of the microphone array may vary. While augmented-reality system 1200 is shown in FIG. 12 as having ten acoustic transducers 1220, the number of acoustic transducers 1220 may be greater or less than ten. In some embodiments, using higher numbers of acoustic transducers 1220 may increase the amount of audio information collected and/or the sensitivity and accuracy of the audio information. In contrast, using a lower number of acoustic transducers 1220 may decrease the computing power required by an associated controller 1250 to process the collected audio information. In addition, the position of each acoustic transducer 1220 of the microphone array may vary. For example, the position of an acoustic transducer 1220 may include a defined position on the user, a defined coordinate on frame 1210, an orientation associated with each acoustic transducer 1220, or some combination thereof.

Acoustic transducers 1220(A) and 1220(B) may be positioned on different parts of the user's ear, such as behind the pinna, behind the tragus, and/or within the auricle or fossa. Or, there may be additional acoustic transducers 1220 on or surrounding the ear in addition to acoustic transducers 1220 inside the ear canal. Having an acoustic transducer 1220 positioned next to an ear canal of a user may enable the microphone array to collect information on how sounds arrive at the ear canal. By positioning at least two of acoustic transducers 1220 on either side of a user's head (e.g., as binaural microphones), augmented-reality device 1200 may simulate binaural hearing and capture a 3D stereo sound field around about a user's head. In some embodiments, acoustic transducers 1220(A) and 1220(B) may be connected to augmented-reality system 1200 via a wired connection 1230, and in other embodiments acoustic transducers 1220(A) and 1220(B) may be connected to augmented-reality system 1200 via a wireless connection (e.g., a Bluetooth connection). In still other embodiments, acoustic transducers 1220(A) and 1220(B) may not be used at all in conjunction with augmented-reality system 1200.

Acoustic transducers 1220 on frame 1210 may be positioned along the length of the temples, across the bridge, above or below display devices 1215(A) and 1215(B), or some combination thereof. Acoustic transducers 1220 may be oriented such that the microphone array is able to detect sounds in a wide range of directions surrounding the user wearing the augmented-reality system 1200. In some embodiments, an optimization process may be performed during manufacturing of augmented-reality system 1200 to determine relative positioning of each acoustic transducer 1220 in the microphone array.

In some examples, augmented-reality system 1200 may include or be connected to an external device (e.g., a paired device), such as neckband 1205. Neckband 1205 generally represents any type or form of paired device. Thus, the following discussion of neckband 1205 may also apply to various other paired devices, such as charging cases, smart watches, smart phones, wrist bands, other wearable devices, hand-held controllers, tablet computers, laptop computers, other external compute devices, etc.

As shown, neckband 1205 may be coupled to eyewear device 1202 via one or more connectors. The connectors may be wired or wireless and may include electrical and/or non-electrical (e.g., structural) components. In some cases, eyewear device 1202 and neckband 1205 may operate independently without any wired or wireless connection between them. While FIG. 12 illustrates the components of eyewear device 1202 and neckband 1205 in example locations on eyewear device 1202 and neckband 1205, the components may be located elsewhere and/or distributed differently on eyewear device 1202 and/or neckband 1205. In some embodiments, the components of eyewear device 1202 and neckband 1205 may be located on one or more additional peripheral devices paired with eyewear device 1202, neckband 1205, or some combination thereof.

Pairing external devices, such as neckband 1205, with augmented-reality eyewear devices may enable the eyewear devices to achieve the form factor of a pair of glasses while still providing sufficient battery and computation power for expanded capabilities. Some or all of the battery power, computational resources, and/or additional features of augmented-reality system 1200 may be provided by a paired device or shared between a paired device and an eyewear device, thus reducing the weight, heat profile, and form factor of the eyewear device overall while still retaining desired functionality. For example, neckband 1205 may allow components that would otherwise be included on an eyewear device to be included in neckband 1205 since users may tolerate a heavier weight load on their shoulders than they would tolerate on their heads. Neckband 1205 may also have a larger surface area over which to diffuse and disperse heat to the ambient environment. Thus, neckband 1205 may allow for greater battery and computation capacity than might otherwise have been possible on a stand-alone eyewear device. Since weight carried in neckband 1205 may be less invasive to a user than weight carried in eyewear device 1202, a user may tolerate wearing a lighter eyewear device and carrying or wearing the paired device for greater lengths of time than a user would tolerate wearing a heavy standalone eyewear device, thereby enabling users to more fully incorporate artificial-reality environments into their day-to-day activities.

Neckband 1205 may be communicatively coupled with eyewear device 1202 and/or to other devices. These other devices may provide certain functions (e.g., tracking, localizing, depth mapping, processing, storage, etc.) to augmented-reality system 1200. In the embodiment of FIG. 12, neckband 1205 may include two acoustic transducers (e.g., 1220(I) and 1220(J)) that are part of the microphone array (or potentially form their own microphone subarray). Neckband 1205 may also include a controller 1225 and a power source 1235.

Acoustic transducers 1220(I) and 1220(J) of neckband 1205 may be configured to detect sound and convert the detected sound into an electronic format (analog or digital). In the embodiment of FIG. 12, acoustic transducers 1220(l) and 1220(J) may be positioned on neckband 1205, thereby increasing the distance between the neckband acoustic transducers 1220(I) and 1220(J) and other acoustic transducers 1220 positioned on eyewear device 1202. In some cases, increasing the distance between acoustic transducers 1220 of the microphone array may improve the accuracy of beamforming performed via the microphone array. For example, if a sound is detected by acoustic transducers 1220(C) and 1220(D) and the distance between acoustic transducers 1220(C) and 1220(D) is greater than, e.g., the distance between acoustic transducers 1220(D) and 1220(E), the determined source location of the detected sound may be more accurate than if the sound had been detected by acoustic transducers 1220(D) and 1220(E).

Controller 1225 of neckband 1205 may process information generated by the sensors on neckband 1205 and/or augmented-reality system 1200. For example, controller 1225 may process information from the microphone array that describes sounds detected by the microphone array. For each detected sound, controller 1225 may perform a direction-of-arrival (DOA) estimation to estimate a direction from which the detected sound arrived at the microphone array. As the microphone array detects sounds, controller 1225 may populate an audio data set with the information. In embodiments in which augmented-reality system 1200 includes an inertial measurement unit, controller 1225 may compute all inertial and spatial calculations from the IMU located on eyewear device 1202. A connector may convey information between augmented-reality system 1200 and neckband 1205 and between augmented-reality system 1200 and controller 1225. The information may be in the form of optical data, electrical data, wireless data, or any other transmittable data form. Moving the processing of information generated by augmented-reality system 1200 to neckband 1205 may reduce weight and heat in eyewear device 1202, making it more comfortable to the user.

Power source 1235 in neckband 1205 may provide power to eyewear device 1202 and/or to neckband 1205. Power source 1235 may include, without limitation, lithium ion batteries, lithium-polymer batteries, primary lithium batteries, alkaline batteries, or any other form of power storage. In some cases, power source 1235 may be a wired power source. Including power source 1235 on neckband 1205 instead of on eyewear device 1202 may help better distribute the weight and heat generated by power source 1235.

As noted, some artificial-reality systems may, instead of blending an artificial reality with actual reality, substantially replace one or more of a user's sensory perceptions of the real world with a virtual experience. One example of this type of system is a head-worn display system, such as virtual-reality system 1300 in FIG. 13, that mostly or completely covers a user's field of view. Virtual-reality system 1300 may include a front rigid body 1302 and a band 1304 shaped to fit around a user's head. Virtual-reality system 1300 may also include output audio transducers 1306(A) and 1306(B). Furthermore, while not shown in FIG. 13, front rigid body 1302 may include one or more electronic elements, including one or more electronic displays, one or more inertial measurement units (IMUs), one or more tracking emitters or detectors, and/or any other suitable device or system for creating an artificial reality experience.

Artificial-reality systems may include a variety of types of visual feedback mechanisms. For example, display devices in augmented-reality system 1200 and/or virtual-reality system 1300 may include one or more liquid crystal displays (LCDs), light emitting diode (LED) displays, organic LED (OLED) displays, digital light project (DLP) micro-displays, liquid crystal on silicon (LCoS) micro-displays, and/or any other suitable type of display screen. Artificial-reality systems may include a single display screen for both eyes or may provide a display screen for each eye, which may allow for additional flexibility for varifocal adjustments or for correcting a user's refractive error. Some artificial-reality systems may also include optical subsystems having one or more lenses (e.g., conventional concave or convex lenses, Fresnel lenses, adjustable liquid lenses, etc.) through which a user may view a display screen. These optical subsystems may serve a variety of purposes, including to collimate (e.g., make an object appear at a greater distance than its physical distance), to magnify (e.g., make an object appear larger than its actual size), and/or to relay (to, e.g., the viewer's eyes) light. These optical subsystems may be used in a non-pupil-forming architecture (such as a single lens configuration that directly collimates light but results in so-called pincushion distortion) and/or a pupil-forming architecture (such as a multi-lens configuration that produces so-called barrel distortion to nullify pincushion distortion).

In addition to or instead of using display screens, some artificial-reality systems may include one or more projection systems. For example, display devices in augmented-reality system 1200 and/or virtual-reality system 1300 may include micro-LED projectors that project light (using, e.g., a waveguide) into display devices, such as clear combiner lenses that allow ambient light to pass through. The display devices may refract the projected light toward a user's pupil and may enable a user to simultaneously view both artificial-reality content and the real world. The display devices may accomplish this using any of a variety of different optical components, including waveguide components (e.g., holographic, planar, diffractive, polarized, and/or reflective waveguide elements), light-manipulation surfaces and elements (such as diffractive, reflective, and refractive elements and gratings), coupling elements, etc. Artificial-reality systems may also be configured with any other suitable type or form of image projection system, such as retinal projectors used in virtual retina displays.

Artificial-reality systems may also include various types of computer vision components and subsystems. For example, augmented-reality system 1200 and/or virtual-reality system 1300 may include one or more optical sensors, such as two-dimensional (2D) or 3D cameras, structured light transmitters and detectors, time-of-flight depth sensors, single-beam or sweeping laser rangefinders, 3D LiDAR sensors, and/or any other suitable type or form of optical sensor. An artificial-reality system may process data from one or more of these sensors to identify a location of a user, to map the real world, to provide a user with context about real-world surroundings, and/or to perform a variety of other functions.

Artificial-reality systems may also include one or more input and/or output audio transducers. In the examples shown in FIG. 13, output audio transducers 1306(A) and 1306(B) may include voice coil speakers, ribbon speakers, electrostatic speakers, piezoelectric speakers, bone conduction transducers, cartilage conduction transducers, tragus-vibration transducers, and/or any other suitable type or form of audio transducer. Similarly, input audio transducers may include condenser microphones, dynamic microphones, ribbon microphones, and/or any other type or form of input transducer. In some embodiments, a single transducer may be used for both audio input and audio output.

While not shown in FIG. 12, artificial-reality systems may include tactile (i.e., haptic) feedback systems, which may be incorporated into headwear, gloves, body suits, handheld controllers, environmental devices (e.g., chairs, floormats, etc.), and/or any other type of device or system. Haptic feedback systems may provide various types of cutaneous feedback, including vibration, force, traction, texture, and/or temperature. Haptic feedback systems may also provide various types of kinesthetic feedback, such as motion and compliance. Haptic feedback may be implemented using motors, piezoelectric actuators, fluidic systems, and/or a variety of other types of feedback mechanisms. Haptic feedback systems may be implemented independent of other artificial-reality devices, within other artificial-reality devices, and/or in conjunction with other artificial-reality devices.

By providing haptic sensations, audible content, and/or visual content, artificial-reality systems may create an entire virtual experience or enhance a user's real-world experience in a variety of contexts and environments. For instance, artificial-reality systems may assist or extend a user's perception, memory, or cognition within a particular environment. Some systems may enhance a user's interactions with other people in the real world or may enable more immersive interactions with other people in a virtual world. Artificial-reality systems may also be used for educational purposes (e.g., for teaching or training in schools, hospitals, government organizations, military organizations, business enterprises, etc.), entertainment purposes (e.g., for playing video games, listening to music, watching video content, etc.), and/or for accessibility purposes (e.g., as hearing aids, visual aids, etc.). The embodiments disclosed herein may enable or enhance a user's artificial-reality experience in one or more of these contexts and environments and/or in other contexts and environments.

The process parameters and sequence of the steps described and/or illustrated herein are given by way of example only and can be varied as desired. For example, while the steps illustrated and/or described herein may be shown or discussed in a particular order, these steps do not necessarily need to be performed in the order illustrated or discussed. The various exemplary methods described and/or illustrated herein may also omit one or more of the steps described or illustrated herein or include additional steps in addition to those disclosed.

The preceding description has been provided to enable others skilled in the art to best utilize various aspects of the exemplary embodiments disclosed herein. This exemplary description is not intended to be exhaustive or to be limited to any precise form disclosed. Many modifications and variations are possible without departing from the spirit and scope of the present disclosure. The embodiments disclosed herein should be considered in all respects illustrative and not restrictive. Reference should be made to the appended claims and their equivalents in determining the scope of the present disclosure.

Unless otherwise noted, the terms “connected to” and “coupled to” (and their derivatives), as used in the specification and claims, are to be construed as permitting both direct and indirect (i.e., via other elements or components) connection. In addition, the terms “a” or “an,” as used in the specification and claims, are to be construed as meaning “at least one of.” Finally, for ease of use, the terms “including” and “having” (and their derivatives), as used in the specification and claims, are interchangeable with and have the same meaning as the word “comprising.”

It will be understood that when an element such as a layer or a region is referred to as being formed on, deposited on, or disposed “on” or “over” another element, it may be located directly on at least a portion of the other element, or one or more intervening elements may also be present. In contrast, when an element is referred to as being “directly on” or “directly over” another element, it may be located on at least a portion of the other element, with no intervening elements present.

As used herein, the term “approximately” in reference to a particular numeric value or range of values may, in certain embodiments, mean and include the stated value as well as all values within 10% of the stated value. Thus, by way of example, reference to the numeric value “50” as “approximately 50” may, in certain embodiments, include values equal to 50±5, i.e., values within the range 45 to 55.

As used herein, the term “substantially” in reference to a given parameter, property, or condition may mean and include to a degree that one of ordinary skill in the art would understand that the given parameter, property, or condition is met with a small degree of variance, such as within acceptable manufacturing tolerances. By way of example, depending on the particular parameter, property, or condition that is substantially met, the parameter, property, or condition may be at least approximately 90% met, at least approximately 95% met, or even at least approximately 99% met.

While various features, elements or steps of particular embodiments may be disclosed using the transitional phrase “comprising,” it is to be understood that alternative embodiments, including those that may be described using the transitional phrases “consisting of” or “consisting essentially of,” are implied. Thus, for example, implied alternative embodiments to a lens that comprises or includes polycarbonate include embodiments where a lens consists essentially of polycarbonate and embodiments where a lens consists of polycarbonate.

1. A device, comprising:
a pair of electrodes; and
a dynamic material disposed between the pair of electrodes, the dynamic material comprising a crystalline microstructure configured to change between at least two states in response to changes in an electric field between the two electrodes.

2. The device of claim 1, wherein the dynamic material comprises a multidomain ferroelectric material configured to undergo a phase transformation to a single domain material.

3. The device of claim 1, wherein the dynamic material comprises a multidomain ferroelectric material configured to undergo microstructural rearrangement.

4. The device of claim 3, wherein the microstructural rearrangement involves at least one of a change in domain size and a change in a magnitude of a refractive index difference.

5. The device of claim 1, wherein the dynamic material comprises an electrostrictive ceramic or crystalline material configured to undergo a phase transformation to a multidomain ferroelectric material.

6. The device of claim 1, wherein the dynamic material comprises an electrostrictive material, the electrostrictive material comprising a crystalline structure that is oriented to have a polar axis that is substantially parallel to an electric field generated when a voltage is applied between the pair of electrodes.

7. The device of claim 6, wherein the electrostrictive material is rhombohedral, monoclinic, or tetragonal under the generated electric field.

8. The device of claim 6, wherein the electrostrictive material is cubic in the absence of the generated electric field.

9. The device of claim 6, wherein the electrostrictive material comprises a single crystal or an oriented ceramic material.

10. The device of claim 6, wherein the electrostrictive material comprises PMN-PT.

11. The device of claim 6, wherein the polar axis is aligned substantially parallel to the generated electric field when the electrostrictive material is in a low temperature phase.

12. The device of claim 11, wherein the electrostrictive material is configured to be transparent when it is in the low temperature phase.

13. A material comprising:
tetragonal lead magnesium niobate-lead titanate (PMN-PT); and
at least one lanthanide series element.

14. The material of claim 13, wherein the at least one lanthanide series element is present at a concentration of approximately 10 mol % or less.

15. The material of claim 13, wherein the at least one lanthanide series element comprises at least one of lanthanum, cerium, praseodymium, neodymium, promethium, samarium, europium, gadolinium, terbium, dysprosium, holmium, erbium, thulium, ytterbium, or lutetium.

16. A plurality of methods comprising:
(I) doping a lead magnesium niobate-lead titanate (PMN-PT) material with at least one lanthanide series element; and
processing the PMN-PT material to form tetragonal PMN-PT, or (II) forming a low refractive index nanostructured grating over a carrier substrate;
forming a high refractive index layer over the low refractive index grating to produce a nanostructured coupling element;
forming an adhesive layer over the nanostructured coupling element; and
affixing the nanostructured coupling element to a high index waveguide.

17. The method of claim 16, wherein forming the nanostructured grating comprises nanoimprint lithography.

18. The method of claim 16, wherein forming the nanostructured grating comprises nano-replication.

19. The method of claim 16, wherein forming the nanostructured grating comprises a roll-to-roll process.

20. The method of claim 16, wherein the nanostructured grating comprises a structure selected from the group consisting of a slanted grating and a blazed grating.

21-36. (canceled)
